(19) United States
(12) Patent Application Publication
(10) Pub. No.: US 2015/0076674 A1
(43) Pub. Date: Mar. 19, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Takeshi MIYAKAWA, Hyogo-ken (JP)

(73) Assignee: KABUSHIKI KAISHA TOSHIBA, Tokyo (JP)

(21) Appl. No.: 14/194,583

(22) Filed: Feb. 28, 2014

(30) Foreign Application Priority Data
Sep. 13, 2013 (JP) 2013-191129

(51) Int. Cl. H01L 23/495; H01L 21/56

(52) U.S. Cl. CPC H01L 23/49562; H01L 23/49568; H01L 21/561
USPC 257/675; 438/122; 257/676

(57) ABSTRACT

According to one embodiment, a semiconductor device includes: a semiconductor chip; a resin which covers the semiconductor chip, and includes first and second surfaces opposite to each other, first and second side surfaces opposite to each other, and third and fourth side surfaces opposite to each other; a first conductive member which is formed on the semiconductor chip on a first surface side, and includes an end portion projecting from the first or second side surface; a second conductive member including an end portion projecting from the first or second side surface; and a metal which is formed on a second surface side of the semiconductor chip, is exposed from the resin body on the second surface side, and includes an end portion thereof exposed from the third and fourth side surfaces on the same plane as the third and fourth side surfaces.

### CROSS-REFERENCE TO RELATED APPLICATION

This application is based upon and claims the benefit of priority from Japanese Patent Application No. 2013-191129, filed Sep. 13, 2013, the entire contents of which are incorporated herein by reference.

### FIELD

Embodiments described herein relate to a semiconductor device and a method of manufacturing the same.

### BACKGROUND

Heat generated by the operation of a semiconductor device affects the operation and reliability of the semiconductor device itself or of electronic equipment on which the semiconductor device is mounted. Particularly, a power semiconductor device generates a large quantity of heat and hence, the removal of heat from the semiconductor device is important.

With respect to the power semiconductor device, for example, there has been proposed a structure where heat is removed from both surfaces, that is, from both the lower surface and the upper surface of the package in which the power semiconductor chip is mounted.

### DESCRIPTION OF THE DRAWINGS

FIG. 1A and FIG. 1B are schematic top plan views of a semiconductor device according to a first embodiment.

FIG. 2A and FIG. 2B are schematic cross-sectional views of the semiconductor device according to the first embodiment.

FIG. 3A and FIG. 3B are schematic top plan views of members which constitute the semiconductor device according to the first embodiment.

FIG. 4A and FIG. 4B are schematic side views of the semiconductor device according to the first embodiment.

FIG. 5 is a view showing a method of manufacturing a semiconductor device according to the first embodiment.

FIG. 6 is a view showing the method of manufacturing a semiconductor device according to the first embodiment.

FIG. 7 is a view showing the method of manufacturing a semiconductor device according to the first embodiment.

FIG. 8 is a view showing the method of manufacturing a semiconductor device according to the first embodiment.

FIG. 9 is a view showing the method of manufacturing a semiconductor device according to the first embodiment.

FIG. 10 is a view showing the method of manufacturing a semiconductor device according to the first embodiment.

FIG. 11 is a view showing the method of manufacturing a semiconductor device according to the first embodiment.

FIG. 12 is a view showing the method of manufacturing a semiconductor device according to the first embodiment.

FIG. 13 is a plan view helpful in showing the manner of operation and advantageous effects of the method of manufacturing a semiconductor device according to the first embodiment.

FIG. 14 is a plan view helpful in showing the manner of operation and advantageous effects of the method of manufacturing a semiconductor device according to the first embodiment.

FIG. 15A and FIG. 15B are schematic plan views of a semiconductor device according to a second embodiment.

FIG. 16A and FIG. 16B are schematic cross-sectional views of the semiconductor device according to the second embodiment.

FIG. 17A and FIG. 17B are schematic cross-sectional views of a semiconductor device according to a third embodiment.

FIG. 18 is a schematic top plan view of a heat radiation member of a semiconductor device according to a fourth embodiment.

### DETAILED DESCRIPTION

According to an embodiment, there is provided a semiconductor device which exhibits high heat dissipation properties and a method of manufacturing the semiconductor device.

In general, according to one embodiment, a semiconductor device includes: a semiconductor chip; a resin body which covers the semiconductor chip, and includes a first surface, a second surface which is arranged on a side opposite to the first surface, first and second side surfaces which intersect with the first and second surfaces and are arranged opposite to each other, and third and fourth side surfaces which intersect with the first and second surfaces and the first and second side surfaces, and are arranged opposite to each other; a first conductive member which is formed on the semiconductor chip on a first surface side, and includes: a main body portion to which the semiconductor chip is connected, and which is exposed from the resin body on the first surface side; and a first electrode terminal which includes an end portion thereof projecting from the first or second side surface; a second conductive member which includes a second electrode terminal with an end portion thereof projecting from the first or second side surface; and a heat removing member which is formed on a second surface side of the semiconductor chip, extending from the resin body on the second surface side, and includes an end portion thereof exposed at the third and fourth side surfaces on the same plane as the third and fourth side surfaces.

Hereinafter, exemplary embodiments are explained in conjunction with drawings. In the explanation made hereinafter, identical parts are given the same symbols in different drawing Figures hereof, and the description of the parts which was previously provided is omitted where appropriate.

### FIRST EMBODIMENT

A semiconductor device of this embodiment includes: a semiconductor chip; a resin body which covers the semiconductor chip, and includes a first surface, a second surface which is arranged on a side opposite to the first surface, first and second side surfaces which intersect with the first and second surfaces and are arranged opposite to each other, and third and fourth side surfaces which intersect with the first and second surfaces and the first and second side surfaces, and are arranged opposite to each other; a first conductive member which is formed on the semiconductor chip on a first surface side, and includes: a main body portion to which the semiconductor chip is connected, and which is exposed from the resin body on the first surface side; and a first electrode terminal which has an end portion thereof projecting from the first or second side surface; a second conductive member which has a second electrode terminal having an end portion thereof projecting from the first or second side surface; and a heat removing member which is formed on a second surface side of the semiconductor chip, is exposed from the resin body on the second surface side, and has an end portion thereof exposed from the third and fourth side surfaces on the same plane as the third and fourth side surfaces.

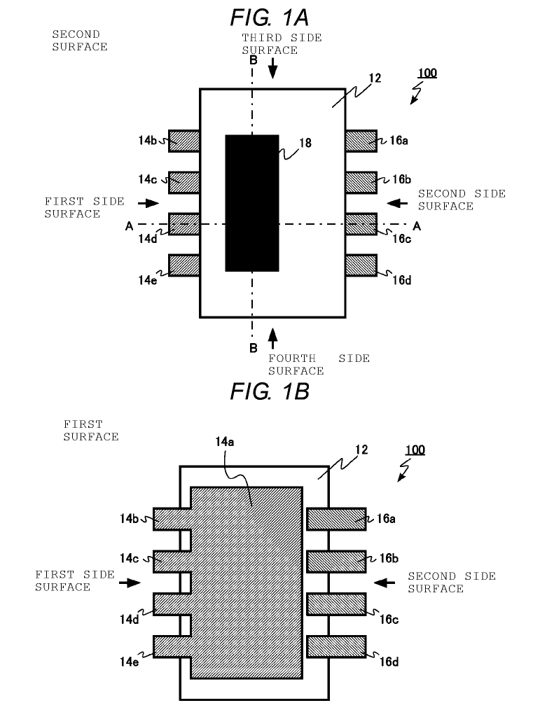

FIG. 1A and FIG. 1B are schematic plan views of the semiconductor device of this embodiment, wherein FIG. 1A is a view of the semiconductor device as viewed from a second surface side of the resin body, and FIG. 1B is a view of the semiconductor device as viewed from a first surface side of the resin body.

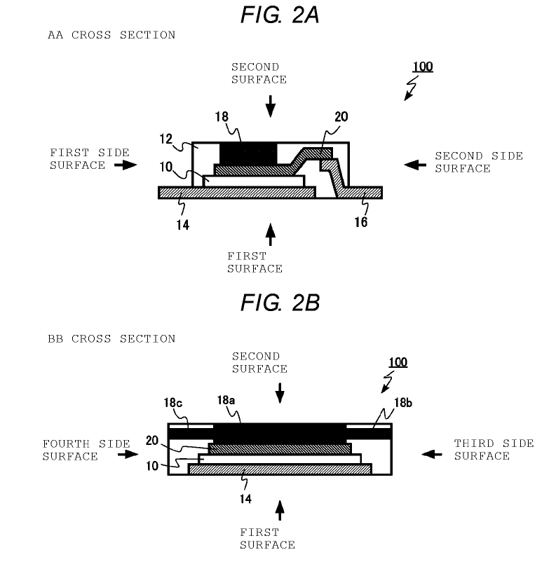

FIG. 2A and FIG. 2B are schematic cross-sectional views of the semiconductor device of this embodiment, wherein FIG. 2A shows a cross section taken along a line A-A in FIG. 1A, and FIG. 2B shows a cross section taken along a line B-B in FIG. 1A.

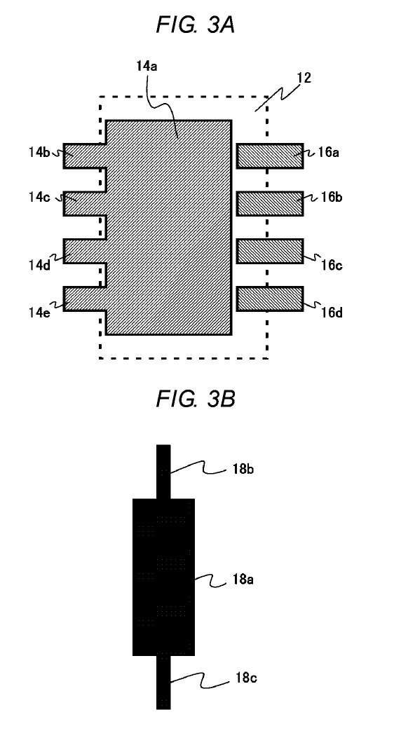

FIG. 3A and FIG. 3B are schematic top plan views of conductive members which form a portion of the package of the semiconductor device of this embodiment, wherein FIG. 3A shows a first conductive member and a second conductive member, and FIG. 3B shows a heat removing member.

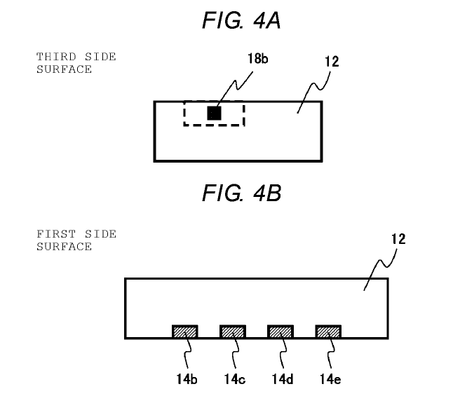

FIG. 4A and FIG. 4B are schematic side views of the semiconductor device of this embodiment, wherein FIG. 4A is a view of the semiconductor device as viewed from a third side surface side of the resin body, and FIG. 4B is a view of the semiconductor device as viewed from a first side surface side of the resin body.

The semiconductor device 100 of this embodiment includes: a semiconductor chip 10; a molded resin body 12; a first electrically conductive member 14; a second electrically conductive member 16; a heat removing member 18; and a third conductive member 20.

The semiconductor chip 10 is a vertical-type MOSFET (Metal Oxide Semiconductor Field Effect Transistor) made of silicon, for example. When the semiconductor chip 10 is a vertical-type MOSFET, a drain electrode (not shown in the drawing) is formed as a lower electrode on the semiconductor chip 10 on one surface side, for example, on a first surface side. A source electrode (not shown in the drawing) and a gate electrode (not shown in the drawing) are formed as upper electrodes on the semiconductor chip 10 on the other surface side, for example, on a second surface side of the semiconductor chip 10.

The molded resin body 12 covers the semiconductor chip 10. The molded resin body 12 is an epoxy-based thermosetting resin to which filler or the like is added, for example.

As shown in FIG. 1A and FIG. 1B, the molded resin body 12 includes: a first surface; a second surface which is arranged on a side opposite to the first surface; first and second side surfaces which intersect with the first and second surfaces and are arranged on sides opposite to each other; and third and fourth side surfaces which intersect with the first and second surfaces and the first and second side surfaces, and are arranged opposite to each other. Although the explanation is made with respect to a case where an outer shape of the molded resin body 12 is a rectangular parallelepiped shape as in this embodiment, the outer shape of the molded resin body 12 is not limited to a rectangular parallelepiped shape. For example, the first and second side surfaces of the molded resin body 12 may be inclined such that a width of the molded resin body 12 gradually increases toward the first surface.

Referring to FIGS. 2A and 3A, the first conductive member 14 is formed on the semiconductor chip 10 on the lower surface side thereof, i.e., on the side of the chip 10 facing the first surface of the molded resin body 12. The first conductive member 14 is made of copper, an iron-nickel alloy or the like, for example. The first conductive member 14 includes a main body portion 14a and four first electrode terminals 14b to 14e.

The semiconductor chip 10 is connected to the main body portion 14a using a bonding material. To be more specific, the semiconductor chip 10 is bonded to the main body portion 14a using an electrically conductive bonding material such as a silver paste or a solder.

As shown in FIG. 1B, a surface of the main body portion 14a is exposed, i.e., it is not covered by but is enclosed about its perimeter by, the molded resin body 12 on the first surface side of the molded resin body 12. Due to such a constitution, heat from the semiconductor chip 10 can be removed or dissipated from the main body portion 14a at the exposed surface of the main body portion, such as by conduction, convection or radiation of heat therefrom.

End portions of four first electrode terminals 14b to 14e project from the first side surface of the molded resin body 12. In other words, the end portions of the first electrode terminals 14b to 14e are not arranged to terminate coplanar with the first side surface, but project outwardly from the first side surface of the molded resin body 12.

The end portions of the first electrode terminals 14b to 14e project from the molded resin body 12 and hence, a solder fillet is formed on three surfaces of the end portions when the semiconductor device 100 is mounted on a printed circuit board or the like by soldering. Accordingly, mounting strength of the semiconductor device 100 is increased so that reliability of the printed circuit board or the like on which the semiconductor device 100 is mounted is enhanced. Further, during an appearance inspection which is carried out after the semiconductor device 100 is mounted on the printed circuit board, since a solder fillet is formed on side surfaces of the package of the semiconductor device 100, whether a mounting state of the semiconductor device 100 is proper or not can be easily determined by observing the semiconductor device 100 from an upper surface side of the printed circuit board.

The projecting amount of the end portions of the first electrode terminals 14b to 14e from the molded resin body 12 is not particularly limited provided that the projecting amount is sufficient for forming a fillet on three surfaces of each end portion. From this point of view, it is desirable that a projecting amount of the end portions of the first electrode terminals 14b to 14e is larger than a thickness of the first electrode terminals 14b to 14e. For example, it is desirable that the projecting amount is 0.1 mm or more, and it is more desirable that the projecting amount is 0.5 mm or more.

When the semiconductor chip 10 is a vertical-type MOSFET, the first electrode terminals 14b to 14e constitute drain terminals.

The second conductive member 16 is made of copper, an iron-nickel alloy or the like, for example. The second conductive member 16 includes four second electrode terminals 16a to 16b.

End portions of four second electrode terminals 16a to 16d project from the second side surface of the molded resin body 12. In other words, the end portions of the second electrode terminals 16a to 16d are not arranged coplanar with the second side surface, i.e., they do not terminate at the side surface, but project outwardly from the second side surface. The second conductive member 16 is formed by bending such that the second conductive member 16 is bent toward a second surface side from a first surface side in the inside of the molded resin body 12. A shape of the second conductive member 16 is not necessarily limited to a bent shape.

The end portions of the second electrode terminals 16a to 16d project from the molded resin body 12 and hence, a solder fillet is formed on three surfaces of each end portion when the semiconductor device 100 is mounted on a printed circuit board or the like by soldering. Accordingly, mounting strength of the semiconductor device 100 is increased so that reliability of the printed circuit board or the like on which the semiconductor device 100 is mounted is enhanced, and visual inspectability of the solder joint is enhanced.

A projecting amount of the end portions of the second electrode terminals 16a to 16d from the molded resin body 12 is not particularly limited as long as the fillet can be formed on three surfaces of the end portion of each second electrode terminal 16a, 16b, 16c, 16d. From this point of view, it is desirable that a projecting amount of the end portions of the second electrode terminals 16a to 16d is preferably larger than a thickness of the second electrode terminals 16a to 16d. For example, it is desirable that the projecting amount is 0.1 mm or more, and it is more desirable that the projecting amount is 0.5 mm or more.

When the semiconductor chip 10 is a vertical-type MOSFET, for example, the second electrode terminal 16a constitutes a gate terminal, and the second electrode terminals 16b to 16d constitute source terminals.

The third conductive member 20 is formed on the semiconductor chip 10 on the second surface side of the chip 10, i.e., on the side of the chip 10 facing the second side of the molded resin body 20. The third conductive member 20 is a connector which electrically interconnects upper electrodes of the semiconductor chip 10 and the second electrode terminals 16b to 16d of the second conductive member 16. The upper electrodes of the chip 10 (not shown) are source electrodes, for example. The third conductive member 20 is made of copper, for example. The second electrode terminal 16a is directly or indirectly connected to the gate electrode (not shown) formed on an upper portion of the semiconductor chip 10, for example.

The third conductive member 20 is adhered to an upper surface of the semiconductor chip 10. To be more specific, the third conductive member 20 is bonded to the semiconductor chip 10 using an electrically conducting bonding material such as a silver paste or a solder.

Referring now to FIGS. 2A, 2B and 3B, the heat removing member 18 is formed on the semiconductor chip 10 on the second surface side of the chip, i.e., the side of chip 10 facing the upper surface side 20 of the molded resin body 20. The heat removing member 18 is made of copper, an iron-nickel alloy or the like, for example. The heat removing member 18 is bonded on the third conductive member 20 using a bonding material such as a silver paste or a solder.

As shown in FIG. 3B, the heat removing member 18 includes a heat removing plate 18a, a first narrowed portion 18b, and a second narrowed portion 18c.

A surface of the heat removing plate 18 is exposed on the second surface side of the molded resin body 12, i.e., the plate 18a is surrounded at its perimeter by the resin, but the face thereof is exposed outwardly of the packaging. Due to such a construction, heat from the semiconductor chip 10 is removed or dissipated from the exposed surface of the heat radiation plate 18a, such as by conductive, convective and radiative heat transfer. The main body portion 14a, adhered to the lower surface of the semiconductor chip 10, and the heat removing plate 18a on an upper surface of the semiconductor chip 10, are arranged so that the semiconductor device 100 has the both-surface heat removing structure where heat is conducted, convected and/or radiated from both surfaces, that is, from the package lower surface and the package upper surface.

The first narrowed portion 18b of the heat removing member 18 is formed on a third side surface side of the heat removing plate 18a. The second narrowed portion 18c is formed on a fourth side surface side of the heat removing plate 18a.

The first narrowed portion 18b and the second narrowed portion 18c function as interlinking members which connect a plurality of heat removing members 18 to each other when a large number of semiconductor devices 100 are molded simultaneously to a framework made up of multiple heat removing plates 18a, that is, the first narrowed portion 18b and the second narrowed portion 18c function as so-called suspension pins. This framework may constitute a sheet or lead frame wherein multiple semiconductor chips may be located, and soldered or affixed, individually or simultaneously. From a viewpoint of facilitating cutting the first narrowed portion 18b and the second narrowed portion 18c in the forming of the molded resin body 12, it is desirable that the first narrowed portion 18b and the second narrowed portion 18c have a smaller width and a smaller thickness than the heat removing plate 18a.

As shown in FIG. 2B and FIG. 4A, the end portion of the first narrowed portion 18b is exposed at the third side surface of the molded resin body 12 substantially coplanar with the third side surface. “The end portion of the first narrowed portion 18b is exposed substantially coplanar with the third side surface” means that the end of the first narrowed portion 18b exists on the same plane as the third side surface to an extent that the third side surface and the end portion of the first narrowed portion 18b are formed in the same cutting step.

As shown in FIG. 2B, the end portion of the second narrowed portion 18c is exposed at the fourth side surface of the molded resin body 12 substantially coplanar with the fourth side surface. “The end portion of the second narrowed portion 18c is exposed substantially coplanar with the fourth side surface” means that the end portion of the second narrowed portion 18c exists on the same plane as the fourth side surface to an extent that the fourth side surface and the end portion of the second narrowed portion 18c are formed in the same cutting step.

In this embodiment, the heat radiation member 18 is not exposed at the first and second side surface of the molded resin body 12, but is encapsulated therein.

The semiconductor device 100 of this embodiment has the both-surface heat removing structure thus realizing a high heat removing or dissipating property. The end portions of the first electrode terminals 14b to 14e and the end portions of the second electrode terminals 16a to 16d project from the molded resin body 12 and hence, mounting strength of the semiconductor device 100 is increased so that reliability of the printed circuit board or the like on which the semiconductor device 100 is mounted is enhanced. The heat removing member 18 includes the heat removing plate 18a, the first narrowed portion 18b, and the second narrowed portion 18c and hence, it is possible to easily manufacture the semiconductor device 100 having the both-surface heat removing structure and the structure where the end portions of the first electrode terminals 14b to 14e and the end portions of the second electrode terminals 16a to 16d project from the molded resin body 12.

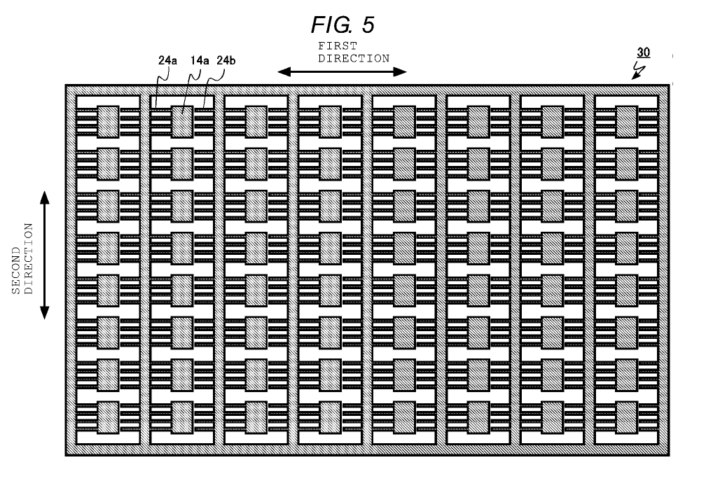

Next, the method of manufacturing a semiconductor device of this embodiment is explained. FIG. 5 to FIG. 12 are views showing the method of manufacturing a semiconductor device of this embodiment.

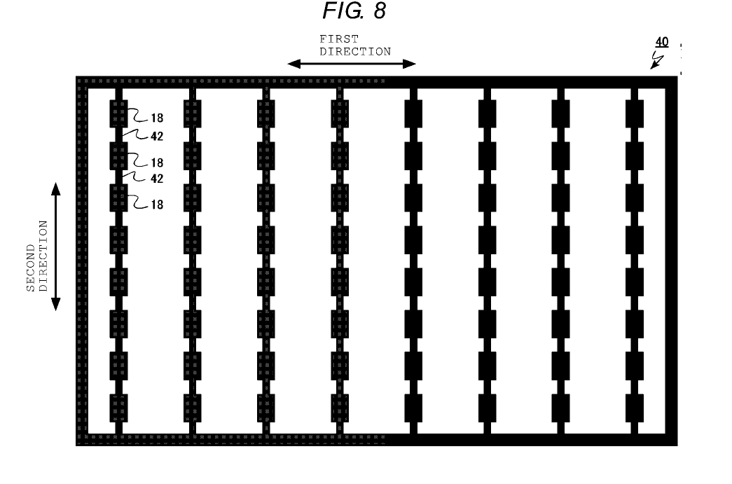

The method of manufacturing a semiconductor device of this embodiment substantially includes the following steps. A lead frame 30 is provided which includes: a plurality of main body portions 14 arranged in a first direction and a second direction orthogonal to the first direction in a matrix array; and electrode terminals which extend in the first direction. A semiconductor chip is mounted on each main body portion 14 of the lead frame 30. Heat removing members 18, which are provided in a frame 40 (FIG. 8) and which are interconnected in a second direction orthogonal to the first direction, are mounted on the semiconductor chips 10 respectively. A resin body is formed such that the resin body collectively covers the semiconductor chips arranged in the second direction and the electrode terminals are exposed along the second direction. The electrode terminals are cut along the second direction. The resin body and the heat removing member are cut along the first direction.

To explain the respective steps, firstly, as shown in FIG. 5, the lead frame 30 is prepared which includes: the plurality of main body portions 14a arranged in the first direction and the second direction orthogonal to the first direction in a matrix array; and electrode terminals 24a, 24b which extend in the first direction which are preforms for the terminals 14b-e. The lead frame 30 is made of copper, an iron-nickel alloy or the like, for example. The lead frame 30 is formed by etching or by press working (stamping), for example.

After such processing, the electrode terminals 24a become the first electrode terminals 14b to 14e of the semiconductor device 100. After such processing, the electrode terminals 24b become the second electrode terminals 16a to 16d of the semiconductor device 100.

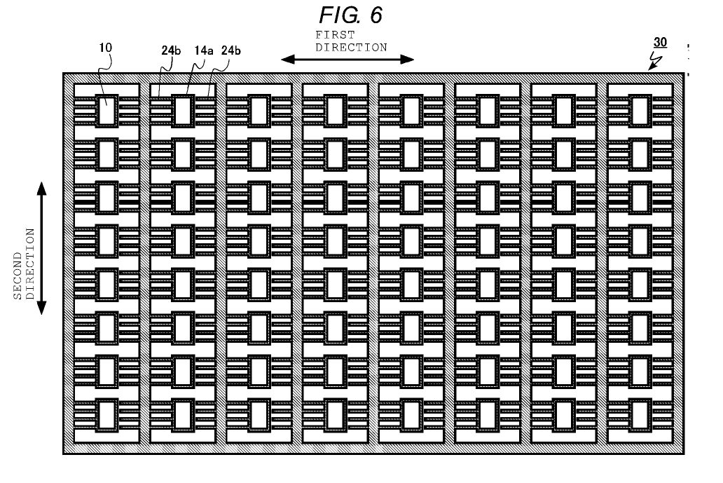

Next, as shown in FIG. 6, the semiconductor chip 10 is mounted on each main body portion 14 of the lead frame 30. For example, the semiconductor chip 10 is mounted on the main body portion 14 using a chip mounter, and is bonded to the main body portion 14 using a bonding material such as a silver paste or a solder, providing both good electrical, and good heat transfer, connection of the chip 10 to the main body portion 14.

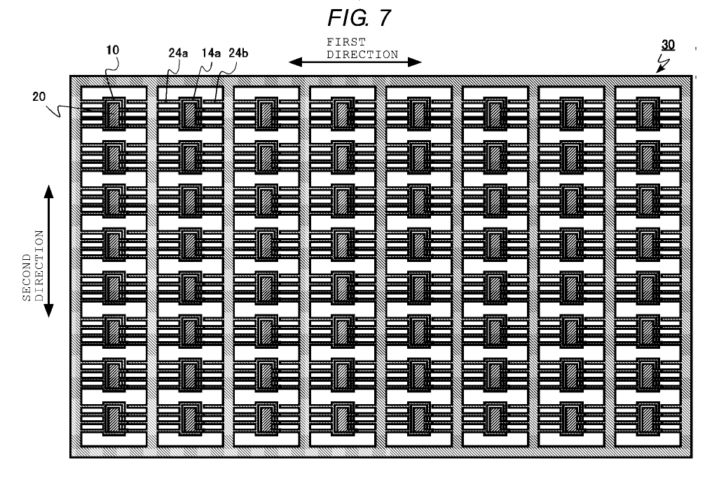

Then, as shown in FIG. 7, a third conductive member 20 is mounted on each semiconductor chip 10. The third conductive member 20 is the connector which electrically connects an upper electrode of the semiconductor chip 10 and the electrode terminal 24b to each other, for example.

Subsequently, as shown in FIG. 8, a frame 40 is prepared which includes a plurality of heat removing members 18 which are interconnected in the second direction. The respective heat removing members 18 are connected to each other by suspension pins 42. After cutting of the frame 40, portions of each suspension pin constitute the first narrowed portions 18b and a second narrowed portions 18c of the heat removing members 18. From a viewpoint of facilitating cutting of the suspension pins 42 during processing, it is desirable that the suspension pin 42 has a smaller width than the heat removing plate 18a. It is also desirable that the suspension pin 42 has a smaller thickness than the heat removing plate 18a.

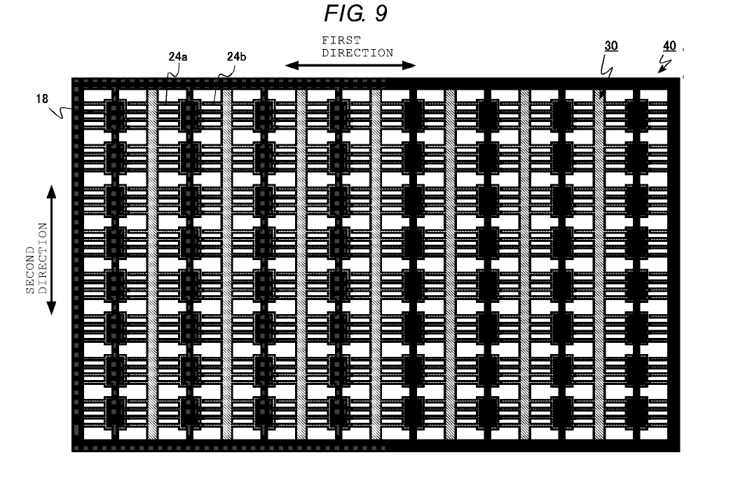

Then, as shown in FIG. 9, the heat removing members 18 which are interconnected in the second direction are mounted on the semiconductor chips 10. To be more specific, the frame 40 which includes the heat removing members 18 is made to overlap with the lead frame 30 on which the semiconductor chips 10 and the third conductive members 20 are mounted, for example. The heat radiation members 18 are bonded to the third conductive members 20 respectively using a bonding material such as a silver paste or a solder, for example.

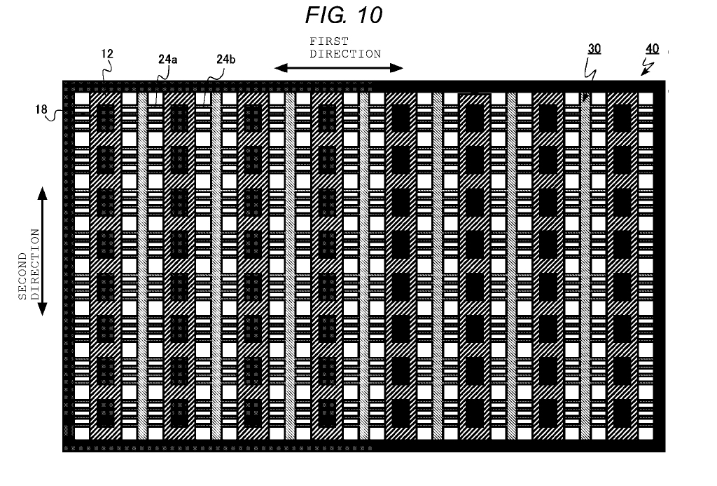

Subsequently, as shown in FIG. 10, a molded resin body 12 is formed such that the molding resin collectively covers the semiconductor chips 10 arranged in the second direction and the electrode terminals 24a, 24b are exposed along the second direction. In forming the molded resin body 12, the molding resin is formed such that the heat removing members 18 are exposed from a surface of the molding resin. In forming the molded resin body 12, the suspension pins 42 which connect the heat removing members 18 to each other are covered with the molding resin.

To be more specific, for example, a hollow die for resin molding which has cavities extending in the second direction is arranged such that the semiconductor chips 10 are accommodated in the cavities. Thereafter, an upper die which covers the surfaces of the heat radiation members 18 is arranged. Then, for example, a thermosetting resin is filled in the cavities, is heated at a predetermined temperature, and is cured by cooling thereafter.

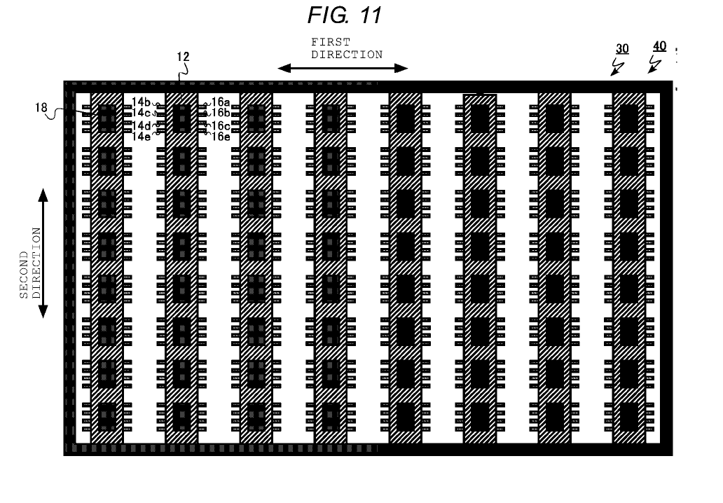

Then, the electrode terminals 24a, 24b are cut along the second direction, resulting in the structure shown in FIG. 11. The cutting of the electrode terminals 24a, 24b is performed using a die cutter, for example.

By cutting the electrode terminals 24a, 24b, first electrode terminals 14b to 14e and second electrode terminals 16a to 16d are formed. End portions of the first electrode terminals 14b to 14e and the end portions of the second electrode terminals 16a to 16d are configured so as to project from the molding resin toward the outside thereof.

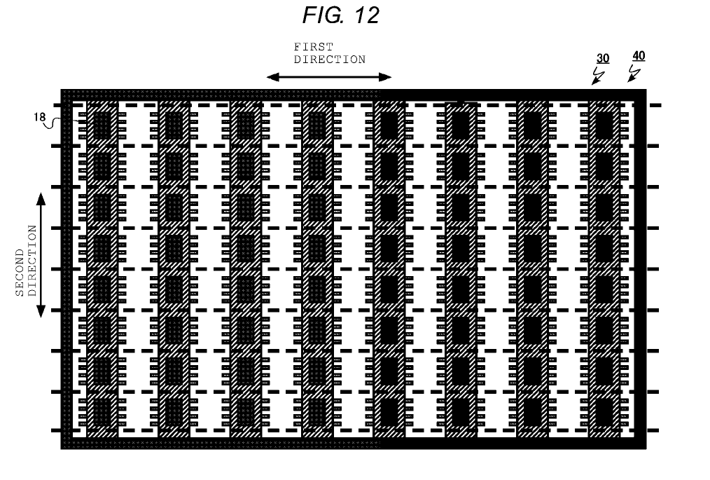

Then, as shown in FIG. 12, the molding resin and the heat removing members 18 are cut along the first direction. To be more specific, the molding resin and suspension pin portions of the heat removing members 18 are simultaneously cut along lines indicated by dotted lines in FIG. 12 by blade dicing with a single blade, for example.

By cutting the molding resin and the heat radiation members 18, end portions of the heat radiation member 18 in the first direction are exposed at the sides of the resulting molded resin body 12 substantially coplanar with a side surface of the molded resin body 12.

The semiconductor devices 100 are manufactured by the manufacturing method explained heretofore.

When the heat removing member 18 is mounted on the plurality of semiconductor chips 10 individually, for example, it is difficult to make surfaces of the respective heat removing members 18 coplanar with each other. When the surfaces of the respective heat removing members 18 cannot be made coplanar with each other, in molding the respective semiconductor chips 10 and the heat removing members 18 collectively by a resin, it is difficult to expose the heat removing members 18 from the surface of the molded resin body 12 in a reliable manner.

According to the manufacturing method of this embodiment, the plurality of heat removing members 18 are mounted on the plurality of semiconductor chips 10 in a state where the heat removing members 18 are connected with each other by the suspension pins. Accordingly, the surfaces of the respective heat removing members 18 can be easily made coplanar with each other. Due to such a constitution, in molding the respective semiconductor chips 10 and the heat removing members 18 by the resin, the heat removing members 18 can be exposed at a the surface of the molded resin body 12 yet surrounded by the resin at the perimeter thereof in a reliable manner.

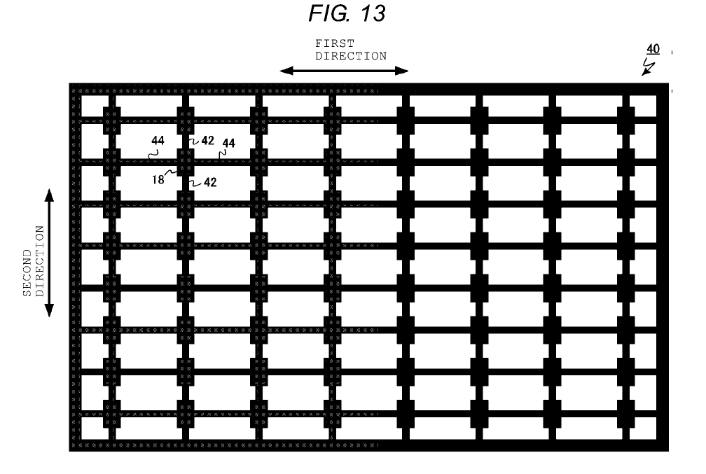

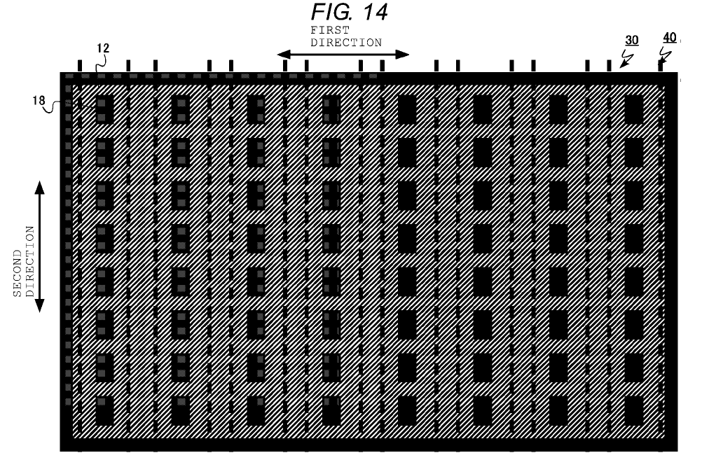

FIG. 13 and FIG. 14 are plan views enabling an explanation of the manner of operation and advantageous effects of the method of manufacturing a semiconductor device of this embodiment. Assuming a case where, as shown in FIG. 13, the heat removing members 18 are connected to each other by four suspension pins in total including suspension pins 44 extending in the first direction and suspension pins 42 extending in the second direction, the suspension pins 44 extending in the first direction and the electrode terminals 24a, 24b extending in the first direction overlap with each other in the vertical direction. Accordingly, when the suspension pins 44 extending in the first direction and the electrode terminals 24a, 24b extending in the first direction are not covered with the molded resin body 12, it is difficult to simultaneously cut the suspension pins 44 extending in the first direction and the electrode terminals 24a, 24b extending in the first direction.

In view of the above, assume a case where, as shown in FIG. 14, the whole semiconductor chip 10 including the suspension pins 44 extending in the first direction and the electrode terminals 24a, 24b extending in the first direction is covered with the molded resin body 12. In this case, the molded resin body 12 is cut along the first direction indicated by dotted lines in the drawing by blade dicing, for example. Due to such a constitution, however, the electrode terminals 24a, 24b cannot be formed in a projecting manner from the molded resin body 12. Accordingly, it is difficult to realize the semiconductor device which has high reliability in a state where the semiconductor device is mounted on a printed circuit board or the like.

According to the manufacturing method of this embodiment, with the use of the frame 40 where the heat removing members 18 are connected to each other only in the second direction, the electrode terminal 24a, 24b can be cut from each other in a state where the ends of the electrode terminals 24a, 24b are not covered with the molded resin body 12. Accordingly, after the cutting of the electrode terminals 24a, 24b from one another, the electrode terminal 24a, 24b can be formed to be projecting from the molded resin body 12. Due to such a manufacturing method, it is possible to realize the semiconductor device having high reliability in a state where the semiconductor device is mounted on a printed circuit board or the like.

As has been explained heretofore, according to this embodiment, it is possible to realize a semiconductor device having high heat removing properties and high reliability, and the method of manufacturing such a semiconductor device.

Although the explanation of the first embodiment has been made by taking the method where the third conductive member 20 is mounted on each semiconductor chip 10 individually as an example, it is also possible to adopt a method where the third conductive members 20 are collectively mounted on the semiconductor chips 10 using a frame which includes a plurality of third conductive members 20 which are connected to each other in the second direction.

### SECOND EMBODIMENT

A semiconductor device of this embodiment differs from the semiconductor device of the first embodiment with respect to the point that the heat removing member includes: a heat removing plate; and a third narrowed portion which is formed on the heat removing plate on a first or second side surface side and has a smaller thickness than the heat removing plate, and a point that the third narrowed portion is connected to a second conductive member. In the explanation made hereinafter, the explanation of the elements of second embodiment which overlaps with the explanation of the elements of the first embodiment is omitted.

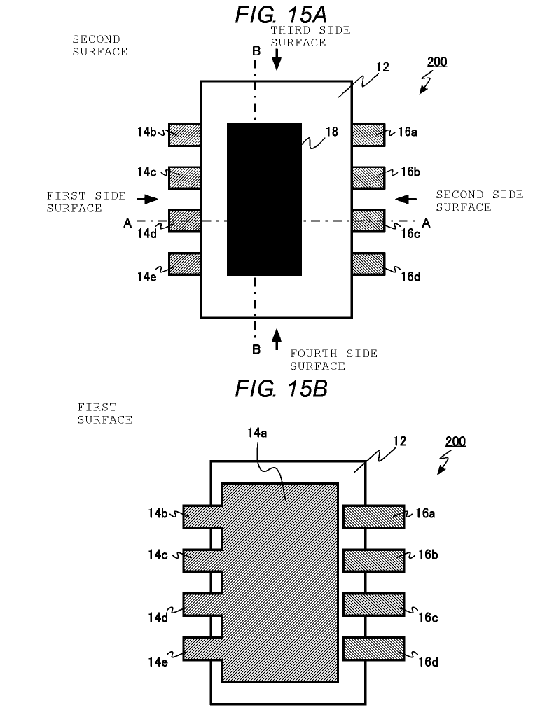

FIG. 15A and FIG. 15B are schematic plan views of the semiconductor device of this embodiment, wherein FIG. 15A is a view of the semiconductor device as viewed from a second surface side of a resin body, and FIG. 15B is a view of the semiconductor device as viewed from a first surface side of the resin body.

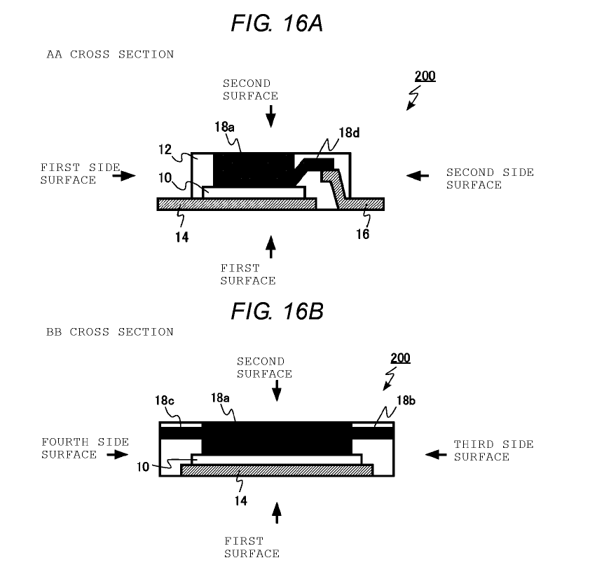

FIG. 16A and FIG. 16B are schematic cross-sectional views of the semiconductor device of this embodiment, wherein FIG. 16A shows a cross section taken along a line A-A in FIG. 15A, and FIG. 16B shows a cross section taken along a line B-B in FIG. 15A.

The semiconductor device 200 of this embodiment includes: a semiconductor chip 10; a molded resin body 12; a first conductive member 14; a second conductive member 16; and a heat removing member 18. Unlike the semiconductor device of the first embodiment, the semiconductor device 200 of this embodiment does not include the member corresponding to the third conductive member 20 of the first embodiment.

The heat removing member 18 includes: a heat removing plate 18a; a first narrowed portion 18b; a second narrowed portion 18c; and a third narrowed portion 18d. The heat removing member 18 is bonded to the semiconductor chip 10 using a bonding material such as a silver paste or a solder, for example.

The third narrowed portion 18d replaces the third conductive member 20 in the first embodiment. That is, the third narrowed portion 18d electrically interconnects an upper electrode of the semiconductor chip 10 and the second conductive member 16.

The third narrowed portion 18d is formed on the heat removing plate 18a on a second side surface thereof, and has a thickness smaller than the heat removing plate 18a. The third narrowed portion 18d is bent so as to be inclined toward a second surface side at a boundary portion between the third narrowed portion 18d and the heat removing plate 18a. Due to such a construction and orientation, an end portion of the heat removing member 18 does not contact an end portion of the semiconductor chip 10 and hence, it is possible to suppress a short-circuit failure or the like which occurs due to leakage of a conductive bonding material used for bonding the heat reducing member 18 and the semiconductor chip 10 to each other, for example. Due to such a construction, for example, the heat removing member 18 is prevented from being brought into contact with and short-circuited with the first conductive member 14.

According to the semiconductor device of the second embodiment, by making use of the heat removing member 18 as a connector, the third conductive member becomes unnecessary and hence, the number of parts can be decreased. Further, an area of a bonding surface for bonding parts is decreased because an intermediate pair of surfaces need not be bonded and hence, the elevation and flatness of an upper surface of the heat removing member 18 can be easily ensured in mounting the heat removing member 18 on the semiconductor chip. Accordingly, the surface of the heat removing member 18 can be exposed at the surface of the molded resin body 12 in a reliable manner.

Along with the decrease of the area of the bonding surface for bonding parts, the heat removing properties of the semiconductor chip 10 is also increased. Further, since the third conductive member becomes unnecessary, it is unnecessary to provide tolerance in alignment between the third conductive member and the heat removing member 18 at the time of manufacturing the semiconductor device. Accordingly, an area of the heat removing member 18 can be increased. The heat removing properties can be enhanced also from this point of view.

A method of manufacturing the semiconductor device 200 of this embodiment can be realized by omitting the step of mounting the third conductive member from the manufacturing method explained in the first embodiment.

As has been explained heretofore, according to this embodiment, it is possible to realize the semiconductor device which can acquire the reduction of the number of parts, the stable manufacturing process and the improved heat radiation property in addition to the advantageous effects acquired by the first embodiment.

### THIRD EMBODIMENT

A semiconductor device of this embodiment differs from the semiconductor device of the second embodiment with respect to a point that the position of a second surface side of a second conductive member is close to the position of a second surface side of a heat removing plate 18a compared to the position of a semiconductor chip side of the heat removing plate 18a and a point that the third narrowed portion has a flat plate shape. In the explanation made hereinafter, the explanation of the elements of the third embodiment which overlap with the explanation of those elements in the second embodiment is omitted.

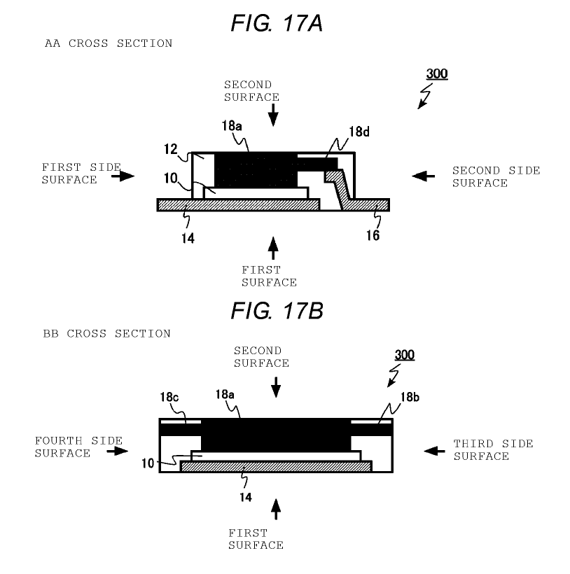

FIG. 17A and FIG. 17B are schematic cross-sectional views of the semiconductor device of this embodiment. An upper surface of the semiconductor device of this embodiment is identical with the upper surface of the semiconductor device of the second embodiment and hence, the upper surface of the semiconductor device of this embodiment is explained in conjunction with FIG. 15A which is the schematic top plan view of the semiconductor device of the second embodiment. FIG. 17A shows a cross section taken along a line A-A in FIG. 15A, and FIG. 17B shows a cross section taken along a line B-B in FIG. 15A.

In the semiconductor device 300 of this embodiment, the third narrowed portion 18d does not have a bent portion and hence, the third narrowed portion 18d is formed in a flat plate shape. This structure can be realized by setting the position of the second surface side of the second conductive member 16 close to the position of the second surface side of the heat removing plate 18a compared to the position of the semiconductor chip side of the heat removing plate 18a.

According to the semiconductor device 300 of this embodiment, the third narrowed portion 18d is formed into a flat plate shape and hence, for example, a path leading to the second conductive member 16 from the semiconductor chip 10 is shortened so that electric resistance therethrough is decreased. Further, it is unnecessary to form the third narrowed portion 18d by bending. Accordingly, working of the heat radiation plate 18a is facilitated and hence, an error in bending is decreased whereby it is possible to realize the semiconductor device having stable characteristics.

As has been explained heretofore, according to this embodiment, it is possible to realize the semiconductor device which can acquire the stable manufacturing process and the stable characteristics in addition to the advantageous effects acquired by the first and second embodiments.

### FOURTH EMBODIMENT

A semiconductor device of this embodiment is substantially equal to the semiconductor device of the first embodiment except for that a heat removing member 18 includes two first narrowed portions 18b and two second narrowed portions 18c. Accordingly, in the explanation made hereinafter, the explanation of the matters of the fourth embodiment which overlap with the matters of the first embodiment is omitted.

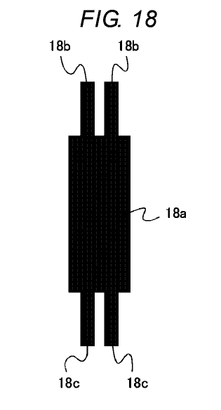

FIG. 18 is a schematic top plan view of a heat removing member of the semiconductor device of this embodiment. As shown in FIG. 18, the heat removing member 18 includes: a heat removing plate 18a; two first narrowed portions 18b; and two second narrowed portions 18c.

According to the semiconductor device of this embodiment, in mounting a plurality of heat removing plates 18 on a plurality of semiconductor chips 10, the plurality of heat radiation plates 18a can be connected to each other in the second direction by two suspension pins which are arranged on each side of the heat removing plate 18a and hence, at the time of mounting the heat removing plates 18a on the semiconductor chips, a positioning control of the heat removing plates 18a on the semiconductor chips 10 is facilitated. Accordingly, the semiconductor device having a stable shape and stable characteristics can be realized.

In the above-mentioned embodiments, the explanation has been made by taking the vertical-type MOSFET as an example of the semiconductor chip. However, the exemplary examples are also applicable to devices other than the vertical-type MOSFET. That is, the exemplary examples are applicable to a vertical-type IGBT (Insulated Gate Bipolar Transistor), a vertical-type SBT (Schottky Barrier Diode) and the like. The exemplary examples are also applicable to a lateral type device where electrodes are formed on either one of an upper surface and a lower surface of a semiconductor chip.

In the embodiment, the explanation has been made by taking the device which uses silicon as semiconductor as an example. However, the semiconductor is not limited to silicon, and carbide semiconductor such as SiC and nitride semiconductor such as GaN-based semiconductor are also applicable.

In the embodiment, the explanation has been made in conjunction with the example where the first conductive member and the second conductive member include four electrode terminals. However, the number of electrode terminals is not limited to four and may be other numbers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

1. A semiconductor device comprising:
a semiconductor chip;
a resin body which covers the semiconductor chip, and includes a first surface, a second surface which is arranged on a side opposite to the first surface, first and second side surfaces which intersect with the first and second surfaces and are arranged opposite to each other, and third and fourth side surfaces which intersect with the first and second surfaces and the first and second side surfaces, and are arranged opposite to each other;
a first conductive member which is formed on the semiconductor chip on a first surface side thereof, and includes: a main body portion to which the semiconductor chip is connected, and a perimeter of the main body that is surrounded by the resin body such that a face thereof is not covered by resin; and a first electrode terminal which includes an end portion thereof projecting from the first or second side surface thereof;
a second conductive member which includes a second electrode terminal with an end portion thereof projecting from the first or second side surface thereof; and
a metal which is formed on a second surface side of the semiconductor chip, and includes a perimeter surrounded by the resin such that a face thereof is not covered by resin, such that end portions thereof extend to the third and fourth side surfaces and terminate on the same plane as the third and fourth side surfaces.

2. The semiconductor device of claim 1, wherein
the metal includes a heat removing plate, and first and second narrowed portions which extend from the third and fourth side surface sides of the heat radiation plate and have a smaller width and a smaller thickness than the heat radiation plate, and
the first and second narrowed portions extend to the third and fourth side surfaces of the device.

3. The semiconductor device of claim 2, wherein the first and second portions extend from the heat removing plate to the third and fourth side surfaces of the device within the resin.

4. The semiconductor device of claim 2, wherein the heat removing plate includes an exposed surface thereof surrounded by the resin, and the first and second narrow portions are offset along the first side surface and second side surface thereof from the exposed surface.

5. The semiconductor device of claim 2, wherein
the heat radiation member includes an additional narrowed portion which is formed on a first or second side surface side of the heat radiation plate and which has a smaller thickness than the heat radiation plate, and
the additional narrowed portion is connected to the second conductive member.

6. The semiconductor device according to claim 5, wherein
a position of the second conductive member on the second surface side is closer to the second surface side of the heat radiation plate than a position of the heat radiation plate on a semiconductor chip side, and
the additional narrowed portion has a flat plate shape.

7. The semiconductor device of claim 6, wherein the second conductive member is the additional narrowed portion.

8. The semiconductor device of claim 1, wherein the second conductive member is interposed between the chip and the metal.

9. The semiconductor device of claim 1, wherein the second conductive member extends from the metal.

10. A method of manufacturing a semiconductor device comprising:
providing a lead frame with a plurality of main body portions interconnected in a first direction and a second direction orthogonal to the first direction in a matrix array therein, and having performs for electrode terminals forming the interconnections in the first direction;
mounting a semiconductor chip on each main body portion of the lead frame;
mounting a heat removing member having a plurality of metal portions interconnected in the second direction, on the semiconductor chips;
forming a resin body such that the resin body collectively covers the semiconductor chips arranged in the second direction and the electrode terminal preforms are exposed along the second direction;
cutting the electrode terminal preforms along the second direction; and
cutting the resin body and the heat radiation member along the first direction.

11. The method of manufacturing a semiconductor device according to claim 10, wherein the steps of cutting the resin body and the heat radiation member along the first direction are performed simultaneously.

12. The method of manufacturing a semiconductor device according to claim 10, wherein the steps of cutting the resin body and the heat radiation member along the first direction are performed with a single cutting tool.

13. The method of manufacturing a semiconductor device according to claim 10, wherein the step of cutting the electrode terminal preforms along the second direction occurs at a position on the preforms spaced from the resin body.

14. The method of manufacturing a semiconductor device according to claim 10, wherein the step of forming a resin body such that the resin body collectively covers the semiconductor chips arranged in the second direction and the electrode terminal preforms are exposed along the second direction includes the steps of:
providing a hollow die having cavities extending in the first direction and spaced apart along the second direction;
aligning the cavities of the hollow die over the rows of main body portions interconnected in a first direction and having a semiconductor chip and a metal disposed on each main body portion in a row;
filling the cavities with resin; and
heating the resin.

15. The method of manufacturing a semiconductor device according to claim 10, further including the step of positioning a conductive member on the semiconductor chip and positioning the metal thereover.

16. The method of manufacturing a semiconductor device according to claim 14, wherein, during the step of filling the cavities with resin, an outer facing surface of the main body portion is left free of resin.

17. The method of manufacturing a semiconductor device according to claim 14, wherein, during the step of filling the cavities with resin, an outer facing surface of the heat removing portion is left free of resin.

18. A semiconductor chip package having a semiconductor chip and an encapsulant around the chip, comprising:
a first conductive plate shaped member received in the encapsulant having at least a portion thereof in electrical contact with the chip and an opposed surface thereof exposed to the exterior of the package; and
a second conductive plate shaped member having at least a portion thereof in electrical contact with the chip at a contact location other than the contact location of the chip and the first plate shaped member and an opposed surface thereof exposed.

19. The semiconductor chip package of claim 18, wherein the first conductive plate includes at least one portion thereof extending outwardly of the resin at a location other than the exposed face thereof.

20. The semiconductor chip package of claim 18, wherein the second conductive plate portion includes at least one extending portion extending therefrom from a location other than the exposed portion thereof, and extending through the resin.
